(19) United States
(12) Patent Application Publication
(10) Pub. No.: US 2006/0227626 A1
(43) Pub. Date: Oct. 12, 2006

(54) Input buffer circuit of semiconductor memory device

(75) Inventors: Shin Ho Chu, Icheon-si (KR); Sang Kwon Lee, Yongin-si (KR)

Correspondence Address: MAYER, BROWN, ROWE & MAW LLP, 1909 K STREET, N.W., WASHINGTON, DC, 20006, US

(73) Assignee: Hynix Semiconductor Inc.

(21) Appl. No.: 11/304,910

(22) Filed: Dec. 16, 2005

(30) Foreign Application Priority Data
Apr. 11, 2005 (KR) 2005-30082

(51) Int. Cl. G11C 7/10

(52) U.S. Cl. 365/189.05

(57) ABSTRACT

An input buffer circuit of a semiconductor memory device, wherein a corresponding memory chip is not always selected regardless of a chip select signal in a power-down operating mode or a self-refresh operating mode. Accordingly, the problem of semiconductor memory device malfunctions in the power-down operating mode or the self-refresh operating mode can be prevented.

### BACKGROUND

1. Field of the Invention

The present invention relates to an input buffer circuit of a semiconductor memory device. More specifically, the present invention relates to an input buffer circuit of a semiconductor memory device, wherein a corresponding memory chip is not always selected regardless of a chip select signal in power-down operating mode or self-refresh operating mode, thus preventing malfunction of the semiconductor memory device.

2. Discussion of Related Art

Generally, semiconductor memory devices such as a DRAM include a buffer circuit for buffering a chip select signal (/CS) which selects one of a plurality of chips and drives the selected chip to output a signal.

FIG. 1 is a circuit diagram of a common input buffer. As shown in FIG. 1, the common input buffer circuit includes a voltage compare unit 10 and an output driver 20.

The voltage compare unit 10 compares a reference voltage (Vref) and a voltage level of a chip select signal (/CS) and outputs a signal having a predetermined level (high or low) according to the comparison result. The voltage compare unit 10 generally consists of a differential amplifier. In this case, the reference voltage (Vref) is a voltage that is compared with the voltage level of the chip select signal (/CS), and is kept to a predetermined voltage level.

The differential amplifier includes an NMOS transistor N1 that is controlled by a clock flag signal (CKE_flag) and enables the voltage compare unit 10, an NMOS transistor N2 controlled by the reference voltage (Vref) and connected between a node A and a node B, an NMOS transistor N3 controlled by the chip select signal (/CS) and connected between the node A and a node C, a PMOS transistor P1 controlled by the clock flag signal (CKE_flag) and connected between a power supply voltage terminal VDD and the node B, a PMOS transistor P2 controlled by a voltage level of the node B and connected between a power supply voltage terminal VDD and the node B, a PMOS transistor P3 controlled by a voltage level of the node B and connected between the power supply voltage terminal VDD and the node C, and a PMOS transistor P4 controlled by the clock flag signal (CKE_flag) and connected between the power supply voltage terminal VDD and the node C, as shown in FIG. 1.

The output driver 20 includes an inverter INV for inverting an output signal of the voltage compare unit 10 and outputting the inverted signal.

Hereinafter, the operation of the common input buffer circuit constructed above will be described in common operating mode and power-down operating mode or self-refresh operating mode. In this case, the term “power-down operating mode” refers to an operating mode for reducing current consumption in order to save power. In this mode a clock enable (CKE) is at a low state and data written into a memory cell is not saved. Further, the term “self-refresh operating mode” is the operating mode for reducing current consumption in order to save power. In this mode a refresh command state along with a clock enable are in a low state, wherein data written into a memory cell is saved.

Common Operating Mode

In the common operating mode, the clock flag signal (CKE_flag) with a high level is input to the gate of the NMOS transistor N1 to enable the voltage compare unit 10. That is, the input buffer circuit is enabled by the clock flag signal (CKE_flag).

As such, if the chip select signal (/CS) with a high level (i.e., a voltage level higher than the reference voltage (Vref)) is input to the gate of the NMOS transistor N3 with the voltage compare unit 10 being enabled by the clock flag signal (CKE_flag), the voltage compare unit 10 outputs a low level signal through the node C. The output driver 20 inverts the output signal of the voltage compare unit 10 and outputs a high level output (output). Thus, a corresponding memory chip is not selected by the high level signal (output).

On the other hand, if the chip select signal (/CS) with a low level (i.e., a voltage level lower than the reference voltage (Vref)) is input to the gate of the NMOS transistor N3 with the voltage compare unit 10 being enabled by the clock flag signal (CKE_flag), the voltage compare unit 10 outputs a high level signal through the node C. The output driver 20 inverts the output signal of the voltage compare unit 10 to output a low level signal (output). Thus, a corresponding memory chip is selected by the low level signal (output).

Power-Down Operating Mode or Self-Refresh Operating Mode

In power-down operating mode or self-refresh operating mode, the clock flag signal (CKE_flag) with a low level is input to the gate of the NMOS transistor N1. Thus, since the NMOS transistor N1 is turned off and the PMOS transistors P1 and P4 are turned on, the voltage compare unit 10 outputs a high level signal having a power supply voltage value.

In power-down operating mode or self-refresh operating mode where the clock flag signal (CKE_flag) is input with the low level, the voltage compare unit 10 always outputs the high level signal through the node C regardless of a voltage level of the chip select signal (/CS). The output driver 20 inverts the output signal of the voltage compare unit 10 and outputs a low level signal (output). Thus, a corresponding memory chip is selected by the low level signal (output).

That is, according to the aforementioned common input buffer circuit, in power-down operating mode or self-refresh operating mode, i.e., when the clock flag signal (CKE_flag) is input as a low level, a corresponding memory chip is always selected regardless of a voltage level of the chip select signal (/CS). Accordingly, in power-down operating mode or self-refresh operating mode, a corresponding memory chip is selected even when the chip select signal (/CS) is at the high level. Therefore, there is a problem in that the semiconductor memory device malfunctions.

### SUMMARY OF THE INVENTION

An advantage of the present invention is an input buffer circuit of a semiconductor memory device, wherein malfunction of the semiconductor memory device in power-down operating mode or self-refresh operating mode can be prevented.

According to an embodiment of the present invention, an input buffer circuit of a semiconductor memory device includes a voltage compare unit, an output controller and an output driver. The voltage compare unit is enabled according to a first level of a clock flag signal to compare a chip select signal and a voltage level of a reference voltage, and outputs a predetermined level signal according to the comparison result. The output controller is enabled according to a second level of the clock flag signal to control the output of the voltage compare unit to be a voltage level of a ground voltage. The output driver inverts the output of the voltage compare unit and outputs the inverted output.

According to another embodiment of the present invention, an input buffer circuit of a semiconductor memory device includes a voltage compare unit and an output driver. The voltage compare unit is enabled according to the first level of the clock flag signal to compare the chip select signal and a voltage level of the reference voltage, and outputs a predetermined level signal according to the comparison result. The output driver decides and outputs a level of an output signal in response to the output of the voltage compare unit and the clock flag signal when the clock flag signal is at the first level, and decides and outputs a level of an output signal in response to the clock flag signal regardless of an output signal of the voltage compare unit when the clock flag signal is at the second level.

As such, in embodiment of the present invention, it is possible to solve a problem in which a semiconductor memory device malfunctions because a memory chip is unnecessarily selected in power-down operating mode or self-refresh operating mode.

### BRIEF DESCRIPTION OF THE DRAWINGS

FIG. 1 is a circuit diagram showing an input buffer circuit of a common semiconductor memory device;

FIG. 2 is a circuit diagram showing an input buffer circuit of a semiconductor memory device according to an embodiment of the present invention;

FIG. 3 is a circuit diagram showing an input buffer circuit of a semiconductor memory device according to another embodiment of the present invention; and

FIG. 4 is a circuit diagram showing an input buffer circuit of a semiconductor memory device according to another embodiment of the present invention.

### DETAILED DESCRIPTION OF PREFERRED EMBODIMENTS

Embodiments according to the present invention will be described with reference to the accompanying drawings. Since embodiments are provided for the purpose of allowing a person of ordinary skill in the art to understand the present invention, they may be modified in various manners and the scope of the present invention is not limited by the embodiments described herein. Like reference numerals are used to identify the same or similar parts.

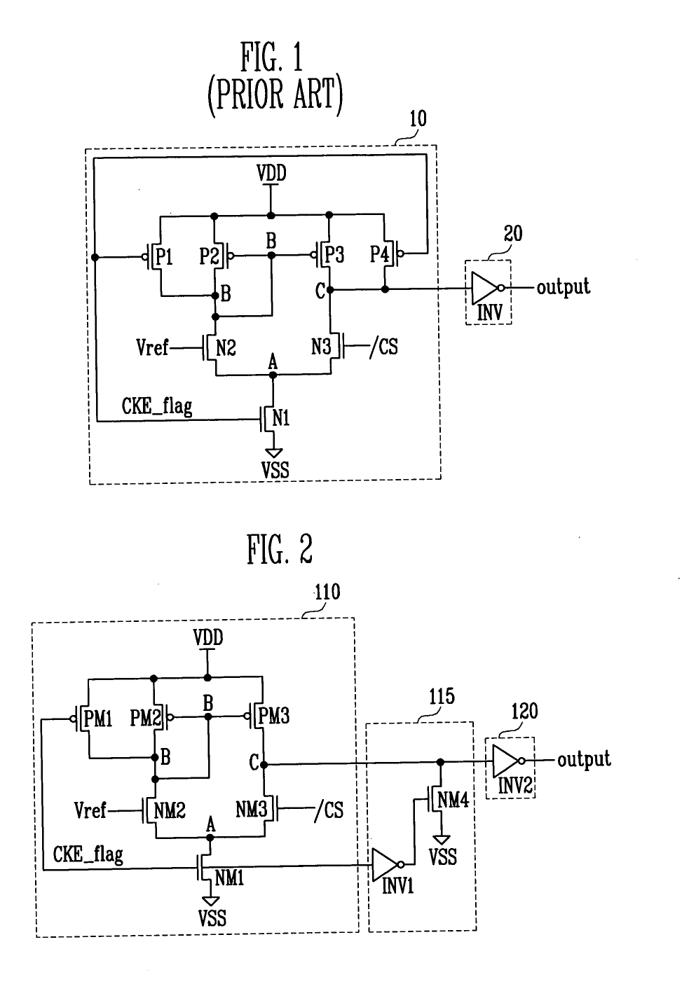

FIG. 2 is a circuit diagram showing an input buffer circuit of a semiconductor memory device according to an embodiment of the present invention.

Referring to FIG. 2, the input buffer circuit according to a first embodiment of the present invention includes a voltage compare unit 110, an output controller 115 and an output driver 120.

The voltage compare unit 110 compares a chip select signal (/CS) and a voltage level of a reference voltage (Vref) and outputs a signal having a predetermined level (high or low) according to the comparison result. The voltage compare unit 110 includes a differential amplifier. In this embodiment, the reference voltage (Vref) is a voltage that is compared with a voltage level of the chip select signal (/CS) and is kept to a predetermined voltage level. The voltage compare unit 110 includes a plurality of NMOS transistors NM1, NM2 and NM3, and a plurality of PMOS transistors PM1, PM2 and PM3.

A clock flag signal (CKE_flag) is a buffered signal of a clock signal. If a mode shifts to a power-down operating mode or a self-refresh operating mode, the clock flag signal shifts from a high level to a low level.

The NMOS transistor NM1 is controlled by the clock flag signal (CKE_flag) and enables the voltage compare unit 110, and is connected between a ground voltage terminal VSS and a node A. The NMOS transistor NM2 is controlled by the reference voltage (Vref) and is connected between the node A and a node B. The NMOS transistor NM3 is controlled by the chip select signal (/CS) and is connected between the node A and a node C. The PMOS transistor PM1 is controlled by the clock flag signal (CKE_flag) and is connected between a power supply voltage terminal VDD and the node B. The PMOS transistor PM2 is controlled according to a voltage level of the node B and is connected between the power supply voltage terminal VDD and the node B. The PMOS transistor PM3 is controlled according to a voltage level of the node B and is connected between the power supply voltage terminal VDD and the node C.

The output controller 115 includes an inverter INV1 for inverting the clock flag signal (CKE_flag), and an NMOS transistor NM4 for connecting an output terminal (node C) of the voltage compare unit 110 and a ground voltage terminal VSS according to the output of the inverter INV1. The output controller 115 controls the output of the voltage compare unit 110 to be a ground voltage level without regard to a voltage level of the chip select signal (/CS) in the power-down operating mode or the self-refresh operating mode, i.e., when the clock flag signal (CKE_flag) with a low level is input to the gate of the NMOS transistor NM1.

The output driver 120 includes an inverter INV2 for inverting the output of the voltage compare unit 110 or the output of the output controller 115. The output driver 120 always generates a high level signal (output) in power-down operating mode or self-refresh operating mode, i.e., when the clock flag signal (CKE_flag) of a low level is input to the gate of the NMOS transistor NM1, so that a corresponding memory chip is not selected.

The operation of the input buffer circuit according to a first embodiment of the present invention will now be described in a common operating mode and the power-down or the self-refresh operating mode.

In the common operating mode the clock flag signal (CKE_flag) with a high level is input to the gate of the NMOS transistor NM1 and the NMOS transistor NM1 is thus turned. Thus, the voltage compare unit 110 is enabled and the NMOS transistor NM4 of the output controller 115 is turned off. Accordingly, the output of the voltage compare unit 110 is transferred to the output driver 120 as it is.

At this time, if the chip select signal (ICS) is at the high level (i.e., a voltage level higher than the reference voltage (Vref)), the NMOS transistor NM3 is turned on and the voltage compare unit 110 outputs a low level signal. The output driver 120 inverts the output signal of the voltage compare unit 110 and outputs a high level signal (output). Thus, a corresponding memory chip is not selected by means of the high level signal (output).

On the other hand, if the chip select signal (/CS) is at a low level (i.e., a voltage level lower than the reference voltage (Vref)), the NMOS transistor NM3 is turned off and the voltage compare unit 10 outputs a high level signal. The output driver 120 inverts the output signal of the voltage compare unit 110 and outputs a low level signal (output). Thus, a corresponding memory chip is selected by means of the low level signal (output).

As described above, in the common operating mode, the output controller 115 does not affect generation of the output signal (output). Thus, the operation of the input buffer circuit is the same as that of the common input buffer circuit.

In the power-down or self-refresh operating mode the clock flag signal (CKE_flag) of a low level is input to the gate of the NMOS transistor NM1 and the NMOS transistor NM1 is thus turned off. As such, as the clock flag signal (CKE_flag) with the low level is input to the gate of the PMOS transistor PM1, the PMOS transistor PM1 of the voltage compare unit 110 is turned on and at the same time, the NMOS transistor NM4 of the output controller 115 is turned on. As the PMOS transistor PM1 is turned on, a high level signal having a power supply voltage value is transferred to the node B, and the PMOS transistors PM2 and PM3 are turned off. As the NMOS transistor NM4 is turned on, the output controller 115 always outputs a low level signal having a ground voltage level regardless of the output of the voltage compare unit 110. The output driver 120 inverts the output of the output controller 115 and outputs a high level signal (output). Thus, a corresponding memory chip is not selected by means of the high level signal (output). That is, the high level signal (output) is always output without regard to a voltage level of the chip select signal (/CS), which in turn prevents a corresponding memory chip from being selected.

In the input buffer circuit according to this embodiment of the present invention, in the power-down operating mode or the self-refresh operating mode, i.e., in a state where the clock flag signal (CKE_flag) of a low level is input to the gate of the NMOS transistor NM1, the NMOS transistor NM4 is turned on, so that the node C and the ground voltage terminal VSS are connected. Accordingly, an output signal of the output controller 115 always becomes a low level regardless of a voltage level of the chip select signal (/CS). Therefore, the output signal (output) of the output driver 120 always becomes a high level.

In the input buffer circuit according to this embodiment of the present invention, a corresponding memory chip is not selected in the power-down operating mode or the self-refresh operating mode. It is thus possible to prevent malfunction of semiconductor memory devices.

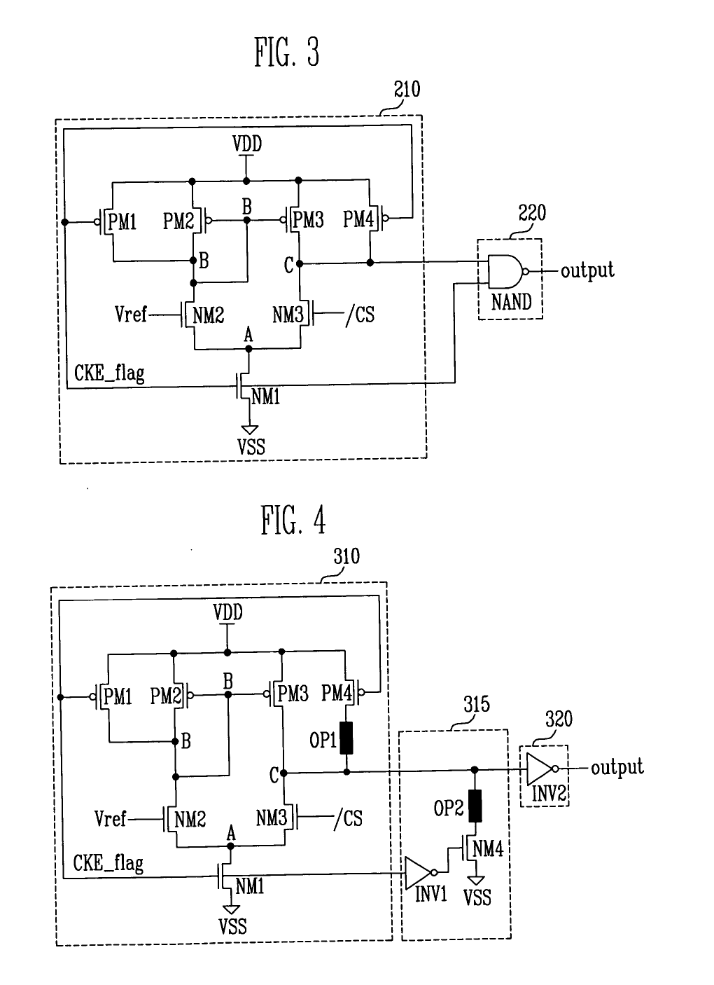

FIG. 3 is a circuit diagram showing an input buffer circuit of a semiconductor memory device according to another embodiment of the present invention.

Referring to FIG. 3, the input buffer circuit according to this embodiment of the present invention includes a voltage compare unit 210 and an output driver 220.

The voltage compare unit 210 compares a chip select signal (/CS) and a voltage level of a reference voltage (Vref), and outputs a signal having a predetermined level (high or low) according to the comparison result. The voltage compare unit 210 includes a differential amplifier. The voltage compare unit 210 has a plurality of NMOS transistors NM1, NM2 and NM3, and a plurality of PMOS transistors PM1, PM2, PM3 and PM4.

The NMOS transistor NM1 is controlled by a clock flag signal (CKE_flag) to enable the voltage compare unit 210, and is connected between a ground voltage terminal and a node A. The NMOS transistor NM2 is controlled by the reference voltage (Vref) and is connected between the node A and a node B. The NMOS transistor NM3 is controlled by the chip select signal (/CS) and is connected between the node A and a node C. The PMOS transistor PM1 is controlled by the clock flag signal (CKE_flag) and is connected between a power supply voltage terminal VDD and the node B. The PMOS transistor PM2 is controlled by a voltage level of the node B and is connected between the power supply voltage terminal VDD and the node B. The PMOS transistor PM3 is controlled by a voltage level of the node B and is connected between the power supply voltage terminal VDD and the node C. The PMOS transistor PM4 is controlled by the clock flag signal (CKE_flag) and is connected between the power supply voltage terminal VDD and the node C.

The output driver 220 includes a NAND gate NAND that performs a NAND operation on the clock flag signal (CKE_flag) and the output signal of the voltage compare unit 210. The output driver 220 controls a corresponding memory chip not to be selected regardless of a voltage level of the chip select signal (/CS) in a power-down operating mode or a self-refresh operating mode, i.e., when the clock flag signal (CKE_flag) of a low level is input to the gate of the NMOS transistor NM1.

Hereinafter, the operation of the input buffer circuit according this embodiment of the present invention will be described in a common operating mode and the power-down or the self-refresh operating mode.

In the common operating mode the clock flag signal (CKE_flag) of a high level is input to the gate of the NMOS transistor NM1 and the NMOS transistor NM1 is thus turned on. Thus, the voltage compare unit 210 is enabled. Furthermore, the clock flag signal (CKE_flag) with the high level is input to the input terminal of the NAND gate NAND, and the output of the voltage compare unit 210 is masked according to the clock flag signal (CKE_flag).

If the chip select signal (/CS) is at the high level (i.e., a voltage level higher than the reference voltage (Vref)), the NMOS transistor NM3 is turned on and the voltage compare unit 210 outputs a low level signal. If the NAND gate receives a low level signal, it always outputs a high level signal. The output driver 220 inverts the output signal of the voltage compare unit 210 and outputs a high level signal (output). Thus, a corresponding memory chip is not selected by means of the high level signal (output).

On the other hand, if the chip select signal (/CS) is at the low level (i.e., a voltage level lower than the reference voltage (Vref)), the NMOS transistor NM3 is turned off and the voltage compare unit 210 outputs a high level signal. The NAND gate performs a NAND operation on the high level signal, i.e., the output of the voltage compare unit 210 and the clock flag signal (CKE_flag) of the high level to output a low level signal. The output driver 220 inverts the output signal of the voltage compare unit 210 and outputs a low level signal (output). Thus, a corresponding memory chip is selected by means of the low level signal (output).

As described above, in common operating mode, the NAND gate NAND of the output driver 220 masks the output of the voltage compare unit 210 to generate the output signal (output). Accordingly, the input buffer circuit operates in the same manner as the common input buffer circuit.

In the power-down or self-refresh operating mode the clock flag signal (CKE_flag) of a low level is input to the gate of the NMOS transistor NM1 and the NMOS transistor NM1 is thus turned off. As the clock flag signal (CKE_flag) of a low level is input to the gate of the PMOS transistor PM1, the PMOS transistor PM1 of the voltage compare unit 210 is turned on. Accordingly, a high level signal having a power supply voltage value is transferred to the node B and the PMOS transistors PM2 and PM3 are turned off. The clock flag signal (CKE_flag) of the low level is also input to one input terminal of the NAND gate. The NAND gate always outputs a high level signal when at least one low level signal is received, and the output driver 220 always outputs a high level signal (output) regardless of the output of the voltage compare unit 210. Accordingly, a corresponding memory chip is not selected by the high level signal (output). In other words, the output driver 220 always outputs a high level signal (output) regardless of a voltage level of the chip select signal (/CS), and a corresponding memory chip is not selected accordingly.

Therefore, in the input buffer circuit according to this embodiment of the present invention, in the power-down operating mode or the self-refresh operating mode, i.e., when the clock flag signal (CKE_flag) of a low level is input to the gate of the NMOS transistor NM1, the clock flag signal (CKE_flag) of a low level is also input to the input terminal of the NAND gate. Accordingly, the output driver 220 can always output a high level signal (output) without regard to the output of the voltage compare unit 210. That is, the input buffer circuit allows a corresponding memory chip not to be selected regardless of a voltage level of the chip select signal (/CS).

The input buffer circuit according to this embodiment of the present invention allows a corresponding memory chip not to be selected in the power-down operating mode or the self-refresh operating mode. It is thus possible to prevent malfunction of semiconductor memory devices.

FIG. 4 is a circuit diagram showing an input buffer circuit of a semiconductor memory device according to another embodiment of the present invention.

Referring to FIG. 4, the input buffer circuit according to this embodiment of the present invention includes a voltage compare unit 310, an output controller 315 and an output driver 320.

The voltage compare unit 310 compares a chip select signal (/CS) and a voltage level of a reference voltage (Vref), and outputs a signal having a predetermined level (high or low) according to the comparison result. The voltage compare unit 310 includes a differential amplifier.

The voltage compare unit 310 has a plurality of NMOS transistors NM1, NM2 and NM3 and a plurality of PMOS transistors PM1, PM2, PM3 and PM4 and enables the voltage compare unit 310. The NMOS transistor NM1 is controlled by the clock flag signal (CKE_flag) and is connected between a ground voltage terminal and a node A. The NMOS transistor NM2 is controlled by the reference voltage (Vref) and is connected between the node A and a node B. The NMOS transistor NM3 is controlled by the chip select signal (/CS) and is connected between the node A and a node C. The PMOS transistor PM1 is controlled by the clock flag signal (CKE_flag) and is connected between the power supply voltage terminal VDD and the node B. The PMOS transistor PM2 is controlled according to a voltage level of the node B and is connected between a power supply voltage terminal VDD and the node B. The PMOS transistor PM3 is controlled according to a voltage level of the node B and is connected between the power supply voltage terminal VDD and the node C. The PMOS transistor PM4 is controlled by the clock flag signal (CKE_flag) and is connected between the power supply voltage terminal VDD and the node C. Between the PMOS transistor PM4 and the node C is provided select means OP1. The select means OP1 can be a fuse, metal, a switch or the like. The output terminal (node C) of the voltage compare unit 310 and the PMOS transistor PM4 can be connected or disconnected by means of the select means OP1, if needed. For example, in the case where the select means OP1 is formed using a fuse, the PMOS transistor PM4 and the node C can be disconnected by cutting the fuse using a laser. In the case where the select means OP1 is formed using metal, the PMOS transistor PM4 and the node C can be disconnected by cutting the metal using an ion beam (e.g., Focused Ion Beam (FIB)). In the case where the select means OP1 is formed using the switch, the PMOS transistor PM4 and the node C can be disconnected by opening the switch.

The output controller 315 includes an inverter INV1 for inverting the clock flag signal (CKE_flag), and an NMOS transistor NM4 for connecting the output terminal (node C) of the voltage compare unit 310 and the ground voltage terminal VSS according to the output of the inverter INV I. Between the output terminal (node C) of the voltage compare unit 310 and the NMOS transistor NM4 is provided select means OP2. The select means OP2 can be a fuse, metal, a switch or the like. The output terminal (node C) of the voltage compare unit 310 and the NMOS transistor NM4 can be connected or disconnected by means of the select means OP2, if needed. The output controller 315 controls the output of the voltage compare unit 310 to be a ground voltage level without regard to a voltage level of the chip select signal (/CS) in power-down operating mode or self-refresh operating mode, i.e., when the clock flag signal (CKE_flag) of a low level is input to the gate of the NMOS transistor NM1.

The output driver 320 includes an inverter INV2 for inverting the output of the output controller 315. The output driver 320 always generates a high level signal (output) in the power-down operating mode or the self-refresh operating mode, i.e., when the clock flag signal (CKE_flag) of a low level is input to the gate of the NMOS transistor NM1, so that a corresponding memory chip is not selected.

The input buffer circuit according to a third embodiment of the present invention has an advantage in that the circuit can be properly constructed according to the need of a user. For example, if the PMOS transistor PM4 and the output terminal (node C) of the voltage compare unit are connected using the select means OP1 and the output terminal (node C) of the voltage compare unit 310 and the NMOS transistor NM4 is disconnected by means of the select means OP2, the aforementioned common input buffer circuit can be implemented. Furthermore, if the output terminal (node C) of the voltage compare unit 310 and the NMOS transistor NM4 are connected using the select means OP2 and the select means OP1 between the output terminal (node C) of the voltage compare unit 310 and the NMOS transistor NM4 is disconnected, the input buffer circuit according first embodiment can be implemented.

As described above, in order to prevent malfunction of semiconductor memory devices in the power-down operating mode or the self-refresh operating mode where the clock flag signal (CKE_flag) of a low level is input, a corresponding memory chip should not be selected regardless of the chip select signal (/CS).

In order to meet this condition, the position of the NMOS transistor NM3 to which the chip select signal (/CS) is input and the position of the NMOS transistor NM2 to which the reference voltage (Vref) is input can be interchanged. Since the chip select signal (/CS) is a variable signal, however, a signal transferred to the node B becomes unstable and a set-up time of the chip select signal (/CS) is rapidly degraded. It is thus impossible to interchange those positions.

Accordingly, the input buffer circuit of the semiconductor memory device in accordance with a variety of embodiments of the present invention includes the output controllers 115, 315 and the output drivers 120, 220, 320 whereby the semiconductor memory device is stably driven even in the power-down operating mode or the self-refresh operating mode.

As described above, according to embodiments of the present invention, a high level signal is always output regardless of a chip select signal in power-down operating mode or self-refresh operating mode, so that a corresponding memory chip is not selected.

Accordingly, malfunction of semiconductor memory devices the in power-down operating mode or the self-refresh operating mode can be prevented.

Although the foregoing description has been made with reference to the embodiments described herein, it is to be understood that changes and modifications of the present invention may be made by ordinary skill in the art without departing from the spirit and scope of the present invention and appended claims.

What is claimed is:

1. An input buffer circuit of a semiconductor memory device, comprising:
a voltage compare unit, which is enabled according to a first level of a clock flag signal to compare a chip select signal and a voltage level of a reference voltage, and outputs a predetermined level signal according to the comparison result;
an output controller, which is enabled according to a second level of the clock flag signal to control the output of the voltage compare unit to be a voltage level of a ground voltage; and
an output driver configured to invert the output of the voltage compare unit and to output the inverted output.

2. The input buffer circuit as claimed in claim 1, further comprising:
a voltage compare unit, which is enabled according to the first level of the clock flag signal to compare the chip select signal and a voltage level of the reference voltage, and outputs a predetermined level signal according to the comparison result; and
an output driver configured to decide and output a level of an output signal in response to the output of the voltage compare unit and the clock flag signal when the clock flag signal is the first level, and to decide and output a level of an output signal in response to the clock flag signal regardless of an output signal of the voltage compare unit when the clock flag signal is the second level.

3. The input buffer circuit as claimed in claim 1, wherein the clock flag signal is a signal that shifts from the first level to the second level when a mode shifts to a power-down operating mode or a self-refresh operating mode, and the first level is a high level and the second level is a low level.

4. The input buffer circuit as claimed in claim 1, wherein the clock flag signal is a buffered signal of a clock signal.

5. The input buffer circuit as claimed in claim 2, wherein the clock flag signal is a signal that shifts from the first level to the second level when mode shifts to a power-down operating mode or a self-refresh operating mode, and the first level is a high level and the second level is a low level.

6. The input buffer circuit as claimed in claim 2, wherein the clock flag signal is a buffered signal of a clock signal.

7. The input buffer circuit as claimed in claim 1, wherein the voltage compare unit comprises:
a first NMOS transistor controlled by the clock flag signal and connected between a ground voltage terminal and a first node;
a second NMOS transistor controlled by the reference voltage and connected between the first node and a second node;
a third NMOS transistor controlled by the chip select signal and connected between the first node and the third node;
a first PMOS transistor controlled by the clock flag signal and connected between a power supply voltage terminal and the second node;
a second PMOS transistor controlled according to a voltage level of the second node and connected between the power supply voltage terminal and the second node; and
a third PMOS transistor controlled according to a voltage level of the second node and connected between the power supply voltage terminal and the third node.

8. The input buffer circuit as claimed in claim 1, wherein the output controller comprises:
an inverter for inverting the clock flag signal and outputting the inverted signal; and
an NMOS transistor controlled according to the output signal of the inverter and connected between an output terminal of the voltage compare unit and the ground voltage terminal.

9. The input buffer circuit as claimed in claim 1, wherein the output driver includes an inverter for inverting an output signal of the voltage compare unit and outputting the inverted signal.

10. The input buffer circuit as claimed in claim 1, wherein the voltage compare unit comprises:
a first NMOS transistor controlled by the clock flag signal and connected between a ground voltage terminal and a first node;
a second NMOS transistor controlled by the reference voltage and connected between the first node and a second node;
a third NMOS transistor controlled by the chip select signal and connected between the first node and a third node;
a first PMOS transistor controlled by the clock flag signal and connected between a power supply voltage terminal and the second node;
a second PMOS transistor controlled according to a voltage level of the second node and connected between the power supply voltage terminal and the second node;
a third PMOS transistor controlled according to a voltage level of the second node and connected between the power supply voltage terminal and the third node; and
a fourth PMOS transistor controlled by the clock flag signal and connected between the power supply voltage terminal and the third node,
wherein select means for connecting or disconnecting the fourth PMOS transistor and the third node is provided between the third node and the fourth PMOS transistor.

11. The input buffer circuit as claimed in claim 1, wherein the output controller comprises:
an inverter for inverting the clock flag signal and outputting the inverted signal; and
an NMOS transistor controlled according to the output signal of the inverter and connected between an output terminal of the voltage compare unit and a ground voltage terminal,
wherein select means for connecting or disconnecting the NMOS transistor and an output terminal of the voltage compare unit is provided between the output terminal of the voltage compare unit and the NMOS transistor.

12. The input buffer circuit as claimed in claim 10, wherein the select means is a fuse, metal or switch, which can be selectively connected or opened.

13. The input buffer circuit as claimed in claim 10, wherein the output driver includes an inverter for inverting the output signal of the voltage compare unit and outputting the inverted signal.

14. The input buffer circuit as claimed in claim 11, wherein the select means is a fuse, metal or switch, which can be selectively connected or opened.

15. The input buffer circuit as claimed in claim 11, wherein the output driver includes an inverter for inverting the output signal of the voltage compare unit and outputting the inverted signal.

16. The input buffer circuit as claimed in claim 1, wherein the voltage compare unit comprises:
a first NMOS transistor controlled by the clock flag signal and connected between a ground voltage terminal and a first node;
a second NMOS transistor controlled by the reference voltage and connected between the first node and a second node;
a third NMOS transistor controlled by the chip select signal and connected between the first node and a third node;
a first PMOS transistor controlled by the clock flag signal and connected between a power supply voltage terminal and the second node;
a second PMOS transistor controlled according to a voltage level of the second node and connected between the power supply voltage terminal and the second node;
a third PMOS transistor controlled according to a voltage level of the second node and connected between the power supply voltage terminal and the third node; and
a fourth PMOS transistor controlled by the clock flag signal and connected between the power supply voltage terminal and the third node,

17. The input buffer circuit as claimed in claim 2, wherein the output driver includes an NAND gate for performing NAND operation on the clock flag signal and the output signal of the voltage compare unit.
